(19) United States
(12) Patent Application Publication
(10) Pub. No.: US 2019/0198461 A1
(43) Pub. Date: Jun. 27, 2019

(54) FORMING A MODIFIED LAYER WITHIN A RADIO FREQUENCY (RF) SUBSTRATE FOR FORMING A LAYER TRANSFERRED RF FILTER-ON-INSULATOR WAFER

(71) Applicant: QUALCOMM Incorporated, San Diego, CA (US)

(72) Inventors: Stephen Alan FANELLI, San Marcos, CA (US); Sinan GOKTEPELI, San Diego, CA (US); George Pete IMTHURN, San Diego, CA (US)

(21) Appl. No.: 15/947,416

(22) Filed: Apr. 6, 2018

Related U.S. Application Data
(60) Provisional application No. 62/608,810, filed on Dec. 21, 2017.
(60) Provisional application No. 62/609,259, filed on Dec. 21, 2017.

(51) Int. Cl. H01L 23/66; H01L 21/268; B23K 26/362; H01L 23/544; H03H 9/64; H03H 9/02

(52) U.S. Cl. CPC H01L 23/66; H01L 21/268; B23K 26/362; H01L 23/544; H01L 2223/6677; H03H 9/02622; H03H 9/02566; H03H 9/02574; H03H 9/64

(57) ABSTRACT

A method of constructing a layer transferred radio frequency (RF) filter-on-insulator wafer includes exposing a front-side of a bulk RF wafer to a laser light source to form a modified layer at a predetermined depth along a horizontal length of the bulk RF wafer. The method also includes bonding the front-side of the bulk RF wafer to a front-side of a semiconductor handle wafer through an insulator layer. The method further includes forming an RF filter layer from the bulk RF wafer. The method also includes selectively etching away the modified layer from the RF filter layer to the predetermined depth to complete the layer transferred RF filter-on-insulator wafer.

### CROSS-REFERENCE TO RELATED APPLICATION

This application claims the benefit of U.S. Provisional Patent Application No. 62/608,810, filed on Dec. 21, 2017, entitled “FORMING A MODIFIED LAYER WITHIN A RADIO FREQUENCY (RF) SUBSTRATE FOR FORMING A LAYER TRANSFERRED RF FILTER-ON-INSULATOR WAFER,” and U.S. Provisional Patent Application No. 62/609,259, filed on Dec. 21, 2017, entitled “FORMING A MODIFIED LAYER WITHIN A RADIO FREQUENCY (RF) SUBSTRATE FOR FORMING A LAYER TRANSFERRED RF FILTER-ON-INSULATOR WAFER,” the disclosures of which are expressly incorporated by reference herein in their entireties.

### TECHNICAL FIELD

Aspects of the present disclosure general relate to integrated circuits (ICs). More specifically, aspects of the present disclosure relate to forming a modified layer within a radio frequency (RF) wafer for forming a layer transferred RF filter-on-insulator wafer.

### BACKGROUND

Designing mobile radio frequency (RF) chips (e.g., mobile RF transceivers) is complicated by added circuit functions for support of communication enhancements, such as fifth-generation (5G) wireless systems. Further design challenges for mobile RF transceivers include analog/RF performance considerations, including mismatch, noise and other performance considerations. Designing these mobile RF transceivers may include using additional passive devices, for example, for suppressing resonance, and/or for performing filtering, bypassing, and coupling.

These mobile RF transceivers may be designed using RF filters. For example, mobile RF transceivers in wireless communication systems generally rely on RF (e.g., acoustic) filters for processing signals carried in the wireless communication system. Many passive devices may be included in these RF filters. In practice, each of these passive devices may include many inductors and capacitors.

These RF filters may include surface acoustic wave (SAW), as well as bulk acoustic wave (BAW) filters. Current SAW filters, as well as BAW filter packages, include 2D inductors on a capping wafer. These 2D inductors generate a vertical magnetic field in the filters, which may interfere with the filters' functionality. There is also insufficient space for integrating additional RF filters. Furthermore, current process flows for SAW/BAW filter packages are complex when fabricating both 2D inductors and through substrate vias (TSVs) for interconnects.

Fabricating high performance acoustic (e.g., SAW/BAW) filters in an efficient and cost-effective manner is problematic. In particular, spacing constraints imposed by using a piezoelectric layer for supporting the acoustic filters generally limit the number of passive devices that may be included in an acoustic filter. Integration of additional passive devices within an acoustic filter would be desirable.

### SUMMARY

A method of constructing a layer transferred radio frequency (RF) filter-on-insulator wafer includes exposing a front-side of a bulk RF wafer to a laser light source to form a modified layer at a predetermined depth along a horizontal length of the bulk RF wafer. The method also includes bonding the front-side of the bulk RF wafer to a front-side of a semiconductor handle wafer through an insulator layer. The method further includes forming an RF filter layer from the bulk RF wafer. The method also includes selectively etching away the modified layer from the RF filter layer to the predetermined depth to complete the layer transferred RF filter-on-insulator wafer.

A radio frequency (RF) filter-on-insulator wafer may include a semiconductor handle wafer. The RF filter-on-insulator may also include an insulator layer directly on a front-side surface of the semiconductor handle wafer. The RF filter-on-insulator may further include an RF filter layer bonded to the front-side surface of the semiconductor handle wafer through the insulator layer, in which a thickness of the RF filter layer is in a range of 1.0 micron to 1.6 microns.

A radio frequency (RF) front end module may include an acoustic filter, comprising a semiconductor handle wafer, an insulator layer directly on a front-side surface of the semiconductor handle wafer, and an RF filter layer bonded to the front-side surface of the semiconductor handle wafer through the insulator layer, in which a thickness of the RF filter layer is in a range of 1.0 micron to 1.6 microns. The RF front end module may also include an antenna coupled to an output of the acoustic filter.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a schematic diagram of a wireless device having a wireless local area network module and a radio frequency (RF) front end module for a chipset.

FIG. 2 shows a cross-sectional view of a radio frequency (RF) integrated circuit fabricated using a layer transfer process, according to aspects of the present disclosure.

FIGS. 3A and 3B are cross-sectional views of a layer transferred radio frequency (RF) filter-on-insulator wafer fabricated using an RF layer transfer process, according to aspects of the present disclosure.

FIG. 4 illustrates a process of fabricating a layer transferred filter-on-insulator wafer using layer transfer and backgrind processes, according to aspects of the present disclosure.

FIG. 5 illustrates a process of fabricating a layer transferred filter-on-insulator wafer using layer transfer and fracture processes, according to aspects of the present disclosure.

FIG. 6 is a process flow diagram illustrating a method of constructing a layer transferred radio frequency filter-on-insulator wafer, according to an aspect of the present disclosure.

FIG. 7 is a block diagram showing an exemplary wireless communication system in which an aspect of the present disclosure may be advantageously employed.

FIG. 8 is a block diagram illustrating a design workstation used for circuit, layout, and logic design of a semiconductor component, such as the RF filter-on-insulator devices disclosed above.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR”, and the use of the term “or” is intended to represent an “exclusive OR”. As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Mobile radio frequency (RF) chips (e.g., mobile RF transceivers) have migrated to a deep sub-micron process node due to cost and power consumption considerations. Mobile RF chips are a major driving force for advancing miniaturization of electronics. While tremendous improvements are being realized for miniaturizing wireless communication subsystems, such as mobile RF transceivers, acoustic filters have not experienced such improvements.

These mobile RF transceivers may be designed using RF filters. For example, mobile RF transceivers in wireless communication systems generally rely on RF (e.g., acoustic) filters for processing signals carried in the wireless communication system. Many passive devices may be included in these RF filters. In practice, each of these passive devices may include many inductors and capacitors. Designing RF filters for mobile RF transceivers involves analog/RF performance considerations, including mismatch, noise and other performance considerations. Designing these RF filters in mobile RF transceivers may include using additional passive devices, for example, for suppressing resonance, and/or for performing filtering, bypassing, and coupling.

Current SAW filters, as well as BAW filter packages, may include additional passive and/or active components. These may interfere with the filters' functionality. There is also insufficient space for integrating more RF filters. Additionally, current process flows for SAW/BAW filter packages are complex when fabricating both 2D inductors and through substrate vias (TSVs) for interconnects.

Fabricating high performance acoustic (e.g., SAW/BAW) filters in an efficient and cost-effective manner is problematic. In particular, spacing constraints imposed by using a piezoelectric layer for supporting the acoustic filters generally limit the number of passive devices within an acoustic filter. Integration of additional passive devices within an acoustic filter is desirable.

Various aspects of the present disclosure provide techniques for forming a modified layer within an RF wafer for forming a layer transferred RF filter-on-insulator wafer. The process flow for semiconductor fabrication of the layer transferred RF filter-on-insulator wafer may include front-end-of-line (FEOL) processes, middle-of-line (MOL) processes, and back-end-of-line (BEOL) processes. It will be understood that the term “layer” includes film and is not to be construed as indicating a vertical or horizontal thickness unless otherwise stated. As described herein, the term “substrate” may refer to a substrate of a diced wafer or may refer to a substrate of a wafer that is not diced. Similarly, the terms “chip” and “die” may be used interchangeably.

Aspects of the present disclosure relate to forming a modified layer within an RF wafer for forming a layer transferred RF filter-on-insulator wafer. The modified layer may be an etch stop layer or an optical marker that provides an end point layer for etching a backside of the RF wafer. This RF wafer may be a lithium tantalate (LT), a lithium niobate (LN), aluminum nitrate (AN) wafer. Alternatively, the modified layer provides a fracture plane. In this example where the modified layer provides a fracture plane, a thermal expansion process or other like process may separate an RF filter layer from the RF wafer.

In one aspect of the present disclosure, the RF filter layer is bonded on a handle wafer using an insulator layer to form the layer transferred RF filter-on-insulator wafer. The layer transferred RF filter-on-insulator wafer may be subsequently processed for providing, for example, a piezoelectric layer of an acoustic filter (e.g., a SAW/BAW filter) using a proprietary layer transfer process. For example, a layer transferred SAW filter-on-insulator is described that operates at higher frequencies relative to conventional SAW filters and BAW filters.

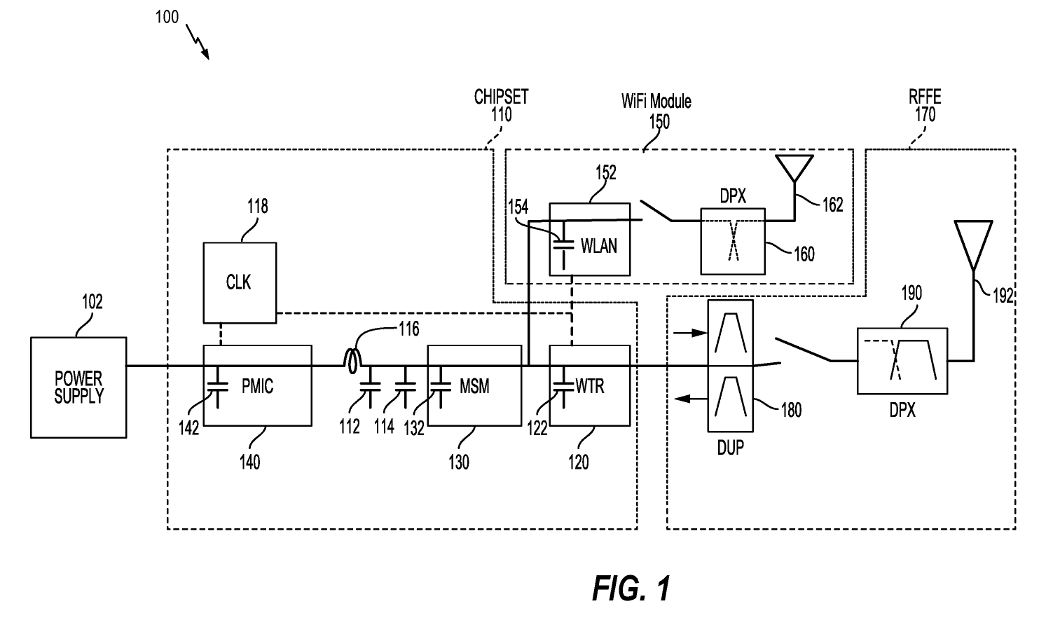

FIG. 1 is a schematic diagram of a wireless device 100 (e.g., a cellular phone or a smartphone) having a filter-on-insulator wafer, according to aspects of the present disclosure. The wireless device may include a wireless local area network (WLAN) (e.g., WiFi) module 150 and an RF front end module 170 for a chipset 110. The WiFi module 150 includes a first diplexer 160 communicably coupling an antenna 162 to a wireless local area network module (e.g., WLAN module 152). The RF front end module 170 includes a second diplexer 190 communicably coupling an antenna 192 to the wireless transceiver 120 (WTR) through a duplexer 180 (DUP).

In this configuration, the wireless transceiver 120 and the WLAN module 152 of the WiFi module 150 are coupled to a modem (MSM, e.g., a baseband modem) 130 that is powered by a power supply 102 through a power management integrated circuit (PMIC) 140. The chipset 110 also includes capacitors 112 and 114, as well as an inductor(s) 116 to provide signal integrity. The PMIC 140, the modem 130, the wireless transceiver 120, and the WLAN module 152 each include capacitors (e.g., 142, 132, 122, and 154) and operate according to a clock 118. The geometry and arrangement of the various inductor and capacitor components in the chipset 110 may reduce the electromagnetic coupling between the components.

The wireless transceiver 120 of the wireless device 100 generally includes a mobile RF transceiver to transmit and receive data for two-way communication. A mobile RF transceiver may include a transmit section for transmitting data and a receive section for receiving data. For transmitting data, the transmit section modulate an RF carrier signal with data for obtaining a modulated RF signal, amplifying the modulated RF signal using a power amplifier (PA) for obtaining an amplified RF signal having the proper output power level, and transmitting the amplified RF signal via the antenna 192 to a base station. For receiving data, the receive section may obtain a received RF signal via the antenna 192, in which the received RF signal is amplified using a low noise amplifier (LNA) and processed for recover data sent by the base station in a communication signal.

The wireless transceiver 120 may include one or more circuits for amplifying these communication signals. The amplifier circuits (e.g., LNA/PA) may include one or more amplifier stages that may have one or more driver stages and one or more amplifier output stages. Each of the amplifier stages includes one or more transistors configured in various ways to amplify the communication signals. Various options exist for fabricating the transistors that are configured to amplify the communication signals transmitted and received by the wireless transceiver 120.

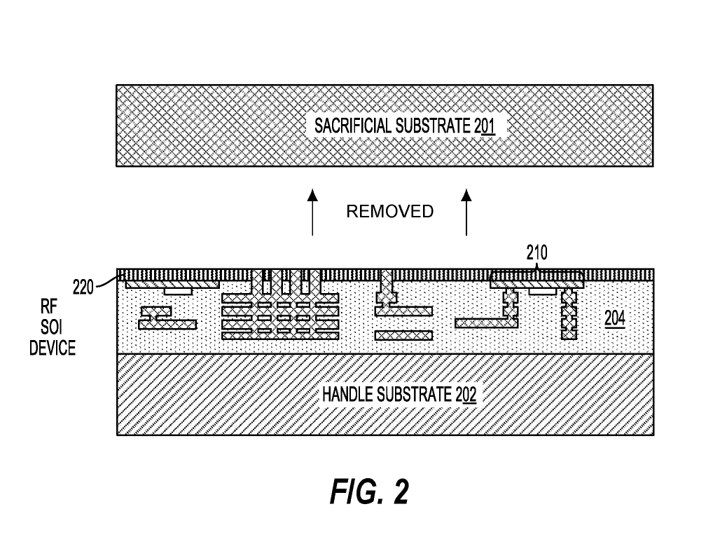

In FIG. 1, the wireless transceiver 120 and the RF front end module 170 may be implemented using complementary metal oxide semiconductor (CMOS) technology. This CMOS technology may be used for fabricating transistors of the wireless transceiver 120 and the RF front end module 170, which helps reduce out-of-band, high order harmonics in the RF front end module 170. A layer transfer (LT) process for further separating an active device from a supporting substrate is shown in FIG. 2.

FIG. 2 show a cross-sectional view of a radio frequency (RF) integrated circuit 200 fabricated using a layer transfer process, according to aspects of the present disclosure. As shown in FIG. 2, an RF SOI device includes an active device 210 on a buried oxide (BOX) layer 220 that is initially supported by a sacrificial substrate 201 (e.g., a bulk wafer). The RF SOI device also includes interconnects 250 coupled to the active device 210 within a first dielectric layer 204. In this configuration, a handle substrate 202 is bonded to the first dielectric layer 204 of the RF SOI device and the sacrificial substrate 201 is removed (see arrows). In addition, bonding of the handle substrate 202 enables removing of the sacrificial substrate 201. Removal of the sacrificial substrate 201 using the layer transfer process enables high-performance, low-parasitic RF devices by increasing the dielectric thickness. That is, a parasitic capacitance of the RF SOI device is proportional to the dielectric thickness, which determines the distance between the active device 210 and the handle substrate 202.

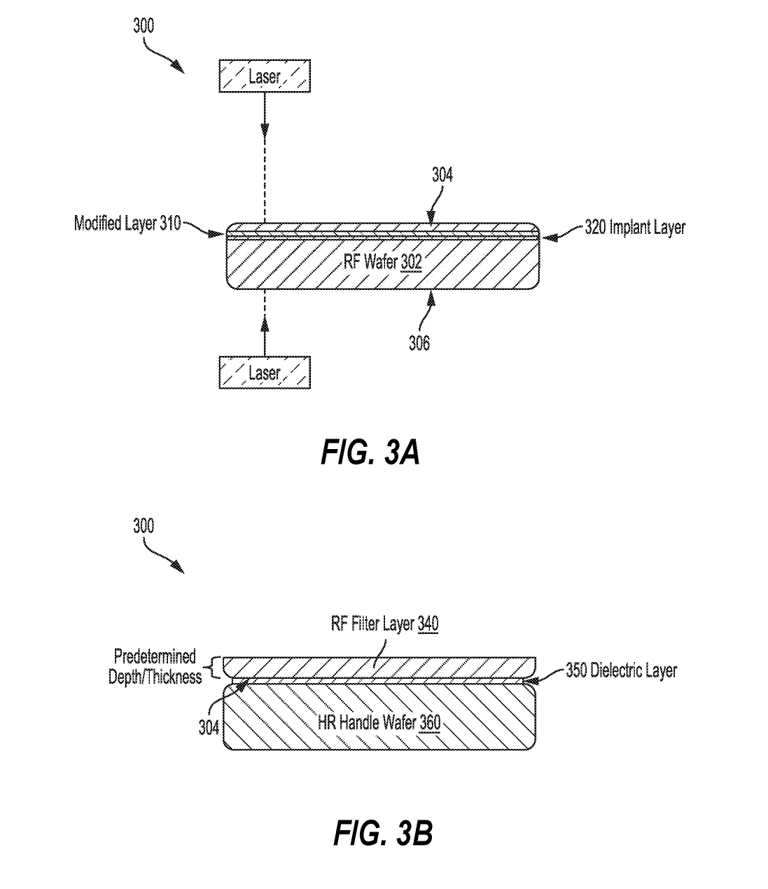

Various aspects of the present disclosure provide techniques for fabricating a modified layer in an RF wafer for forming a layer transferred RF filter-on-insulator wafer, as shown in FIGS. 3A and 3B. In one example, the wafer is a 200 mm diameter wafer.

FIGS. 3A and 3B are cross-sectional views of a layer transferred RF filter-on-insulator wafer 300 fabricated using a layer transfer process, according to aspects of the present disclosure. FIG. 3A illustrates forming a modified layer 310 (e.g., a modified etch stop layer or optical marker) in a bulk RF wafer 302, according to aspects of the present disclosure. Representatively, one or more laser beams are focused at a specific depth through a front-side surface 304 opposite a backside surface 306 of the bulk RF wafer 302. In this example, an implant layer 320 (optional) is also shown for aiding in focusing the laser (e.g., a high pulse rate, such as a femtosecond pulsed laser or a picosecond pulsed laser) to a predetermined depth. Operation of the laser forms the modified layer 310. For example, the laser melts the layer or changes the characteristics of the layer, such as crystal to poly-crystal. The modified layer 310 and the implant layer 320 enable forming of an RF filter layer 340 as shown in FIG. 3B.

FIG. 3B is a cross-sectional view of the layer transferred RF filter-on-insulator wafer 300, according to aspects of the present disclosure. In this configuration, the front-side surface 304 of the bulk RF wafer 302 is bonded to a high resistivity (HR) handle wafer 360 using a dielectric layer 350 (e.g., an insulator layer) of FIG. 3B. In this example, the backside surface 306 of the bulk RF wafer 302 is removed to form an RF filter layer 340 having a predetermined thickness, for example, in the range of 0.5 microns (μm) to 1.9 μm. In one aspect of the present disclosure, the predetermined thickness of the RF filter layer 340 is, for example, 1.0 μm to 1.6 μm, and generally greater than 9 μm. In addition, the HR handle wafer 360 may be a high resistivity silicon handle wafer, including a trap rich layer.

In this aspect of the present disclosure, the layer transferred RF filter-on-insulator wafer 300 is ready for acoustic filter processing. For example, the layer transferred RF filter-on-insulator wafer 300 may be subjected to a further etch process, for example, for forming interdigitated fingers of a surface acoustic wave (SAW) filter. While bulk acoustic wave (BAW) filters may conventionally support higher frequencies than SAW filters, the layer transferred RF filter-on-insulator wafer 300 enables SAW filters that surpass frequencies supported by BAW filters by adjusting a pitch between the interdigitated fingers of a SAW filter formed from the layer transferred RF filter-on-insulator wafer 300.

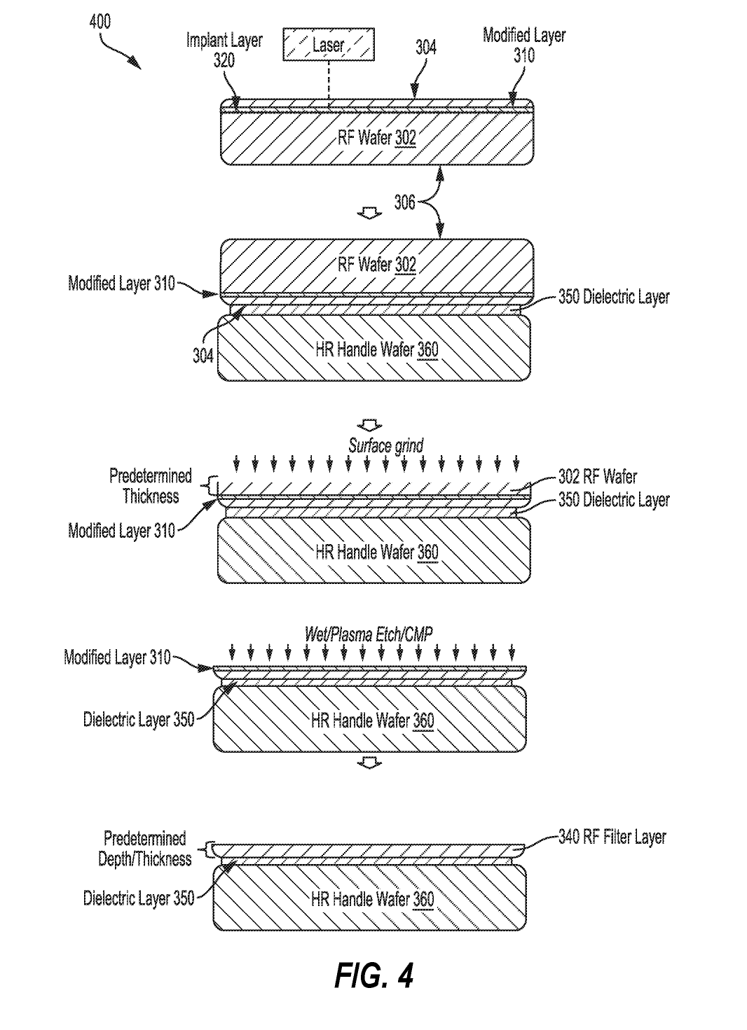

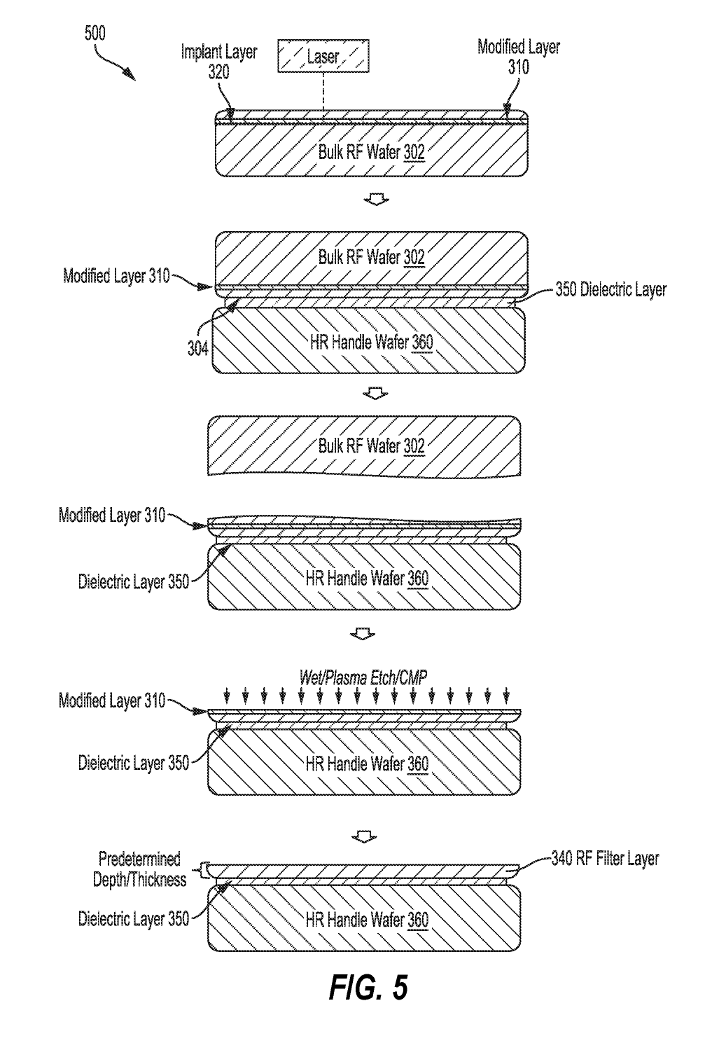

Depending on a bond strength provided by the dielectric layer 350, the modified layer 310 may operate as a fracture plane or a modified etch stop layer. For a high strength bond, a post bonding anneal process may fracture and exfoliate the bulk RF wafer 302 along the modified layer 310. Any remaining portion of the modified layer 310 is then removed by a combination of a wet/plasma etch process, and/or a chemical mechanical planarization (CMP) process to complete the layer transferred RF filter-on-insulator wafer 300, as shown in FIG. 5. Alternatively, the modified layer 310 operates as a modified etch stop layer for an end-point detection process, for example, as shown in FIG. 4.

FIG. 4 illustrates a process 400 of fabricating a layer transferred filter-on-insulator wafer using layer transfer and backgrind processes, according to aspects of the present disclosure. In Step 1, a laser is focused to a specific depth for creating the modified layer 310 in the bulk RF wafer 302. Optionally, the implant layer 320 may be used for focusing the layer at a specific depth, which is also illustrated in FIG. 3A. In Step 2, the front-side surface of the bulk RF wafer 302 is bonded to the HR handle wafer 360.

In this alternative configuration, at Step 3, the backside surface 306 of the bulk RF wafer 302 is thinned using a surface grinding process, although other processes for thinning the bulk RF wafer 302 from the backside surface 306 are possible. This surface grind process may be performed to a predetermined level (e.g., 2-10 μm) above the modified layer 310. At Step 4, the backside surface 306 of the bulk RF wafer 302 is subjected to a combination of methods (e.g., wet etch, plasma etch, and/or chemical mechanical polish (CMP)) to expose the modified layer 310. In this example, a refractive index of the modified layer 310 is different than a refractive index of the bulk RF wafer 302. As a result, the different refractive index of the modified layer 310 is used as an optical endpoint of the wet/plasma etch/CMP of the backside of the bulk RF wafer 302 for exposing a surface of the modified layer 310.

In Step 5, the exposed surface of the modified layer 310 is subjected to a combination of wet etch, plasma etch, and/or CMP for forming an RF filter layer 340. Removal of the modified layer 310 completes forming of the layer transferred RF filter-on-insulator wafer 300 shown in FIGS. 3B and 4. According to aspects of the present disclosure, the predetermined depth/thickness of the RF filter layer 340 may be greater than 0.9 μm, and may be in the range of 1.0 μm up to approximately 1.6 μm.

FIG. 5 illustrates a process 500 of fabricating a layer transferred filter-on-insulator wafer using layer transfer and fracture processes, according to aspects of the present disclosure. The process 500 of fabricating a layer transferred filter-on-insulator wafer is similar to the process 400 of FIG. 4. For example, Step 1 and Step 2 are the same in both the process 400 and the process 500. In Step 3 of the process 500, however, a post bonding and anneal process causes a fracture at the modified layer 310. The bonding adds heat, which may cause the fracture. The fracture at the modified layer 310 removes a portion of the bulk RF wafer 302, similar to an exfoliation process, for exposing portions of the modified layer 310. In Step 4, the exposed portions of the modified layer 310 are subjected to a combination of wet etch, plasma etch, and/or CMP for forming an RF filter layer 340. In Step 5, removal of the modified layer 310 completes forming of the layer transferred RF filter-on-insulator wafer 300 shown in FIGS. 3B, 4, and 5.

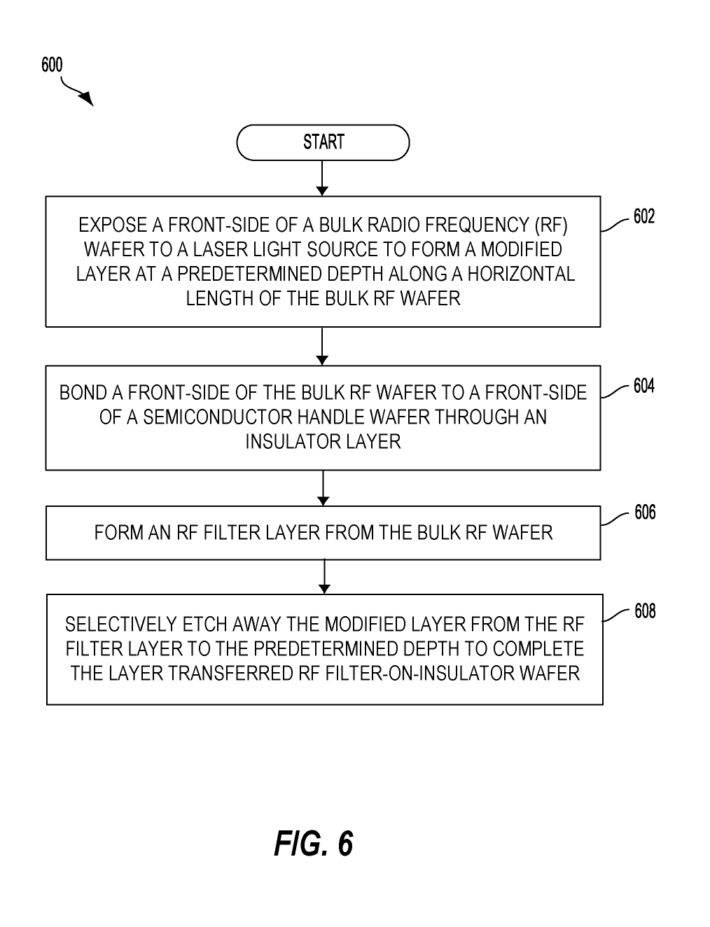

Aspects of the present disclosure use layer transfer processes for forming the layer transferred RF filter-on-insulator wafer 300, for example, as shown in FIGS. 3B, 4, and 5. Although described with reference to a SAW filter, it should be recognized that other RF filters may be fabricated according to aspects of the present disclosure, for example, as shown in FIG. 6.

FIG. 6 is a process flow diagram 600 illustrating a method of constructing a radio frequency (RF) filter-on-insulator wafer, according to an aspect of the present disclosure. At block 602, a front-side of a bulk RF wafer is exposed to a laser light source for forming a modified layer at a predetermined depth along a horizontal length of the bulk RF wafer. For example, as shown in FIG. 3A, the laser is focused at a specific depth through the front-side surface 304 of the bulk RF wafer 302. The laser light source may be provided by a femtosecond or picosecond pulsed laser. In this example, the implant layer 320 (optional) is also shown for aiding in the focusing of the laser to the predetermined depth. Operation of the laser forms the modified layer 310. In block 604, a front-side of the RF wafer is bonded to a front-side of a semiconductor handle wafer through an insulator layer, for example, as shown in Step 2 of FIGS. 4 and 5.

In block 606, an RF filter layer is formed from the RF wafer, for example, as shown in FIGS. 3B, 4, and 5. The modified layer 310 may operate as a fracture plane or a modified etch stop layer for an end point detection process for forming the RF filter layer 340, as shown in FIG. 3B. In block 608, the modified layer is selectively etched away from the RF filter layer to the predetermined depth to complete the layer transferred RF filter-on-insulator wafer. For example, as shown in FIG. 3B, the backside surface of the bulk RF wafer 302 is subjected to a combination of methods for exposing the modified layer 310 for completing formation of the layer transferred RF filter-on-insulator wafer 300. A predetermined depth of the RF filter layer 340 of the layer transferred RF filter-on-insulator wafer 300 may be in the range of 1.0 μm to approximately 1.6 μm, and generally greater than 0.9 μm.

The layer transferred RF filter-on-insulator wafer 300 may be subjected to a further etch process for forming a first set of fingers for a surface acoustic wave (SAW) filter. A second set of fingers are subsequently formed and interdigitated with the first set of fingers to complete the SAW filter. Although bulk acoustic wave (BAW) filters may conventionally support higher frequencies than SAW filters, the layer transferred RF filter-on-insulator wafer 300 enables SAW filters that surpass frequencies supported by BAW filters by adjusting a pitch between the interdigitated fingers of the SAW filter. This process also enables integration of multiple SAW filters within the layer transferred RF filter-on-insulator wafer.

According to a further aspect of the present disclosure, a layer transferred RF filter-on-insulator wafer is described. The layer transferred RF filter-on-insulator wafer includes means for handling the layer transferred RF filter-on-insulator wafer. The handling means may be the handle wafer 360, shown in FIG. 3B. In another aspect, the aforementioned means may be any module, layer or any apparatus configured to perform the functions recited by the aforementioned means.

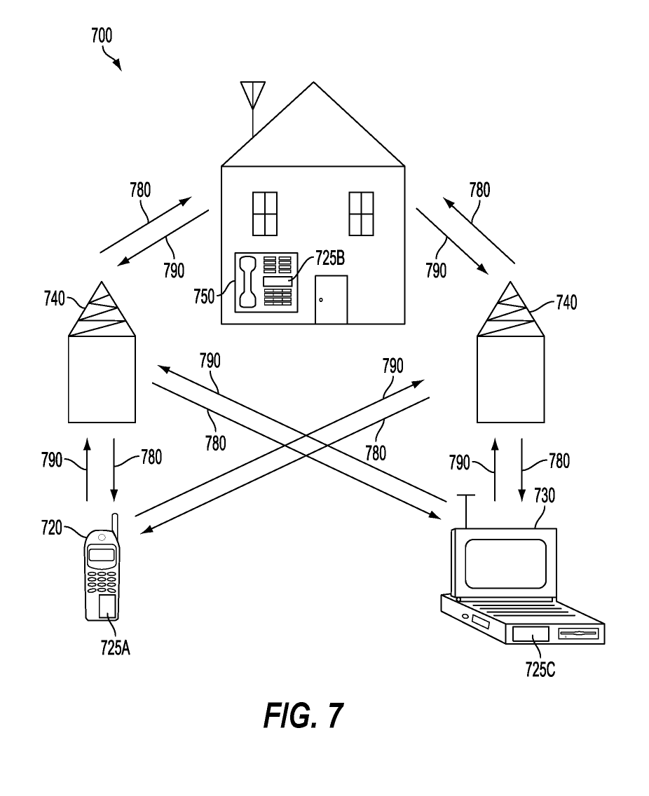

FIG. 7 is a block diagram showing an exemplary wireless communication system 700 in which an aspect of the present disclosure may be advantageously employed. For purposes of illustration, FIG. 7 shows three remote units 720, 730, and 750 and two base stations 740. It will be recognized that wireless communication systems may have many more remote units and base stations. Remote units 720, 730, and 750 include IC devices 725A, 725C, and 725B that include the disclosed layer transferred RF filter-on-insulator wafer. It will be recognized that other devices may also include the disclosed layer transferred RF filter-on-insulator wafer, such as the base stations, switching devices, and network equipment. FIG. 7 shows forward link signals 780 from the base station 740 to the remote units 720, 730, and 750 and reverse link signals 790 from the remote units 720, 730, and 750 to base stations 740.

In FIG. 7, remote unit 720 is shown as a mobile telephone, remote unit 730 is shown as a portable computer, and remote unit 750 is shown as a fixed location remote unit in a wireless local loop system. For example, a remote units may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 7 illustrates remote units according to the aspects of the present disclosure, the present disclosure is not limited to these exemplary illustrated units. Aspects of the present disclosure may be suitably employed in many devices, which include the disclosed layer transferred RF filter-on-insulator wafer.

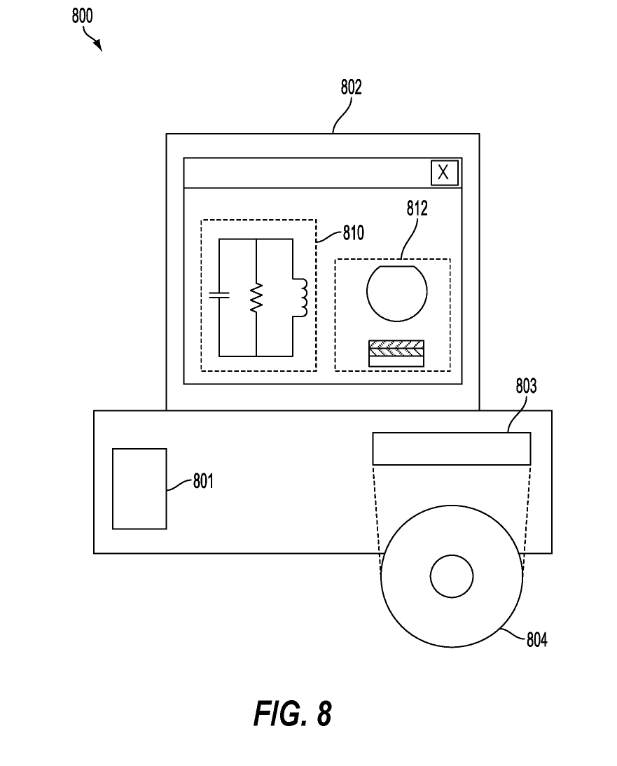

FIG. 8 is a block diagram illustrating a design workstation used for circuit, layout, and logic design of an RF component, such as the RF filter-on-insulator wafer disclosed above. A design workstation 800 includes a hard disk 801 containing operating system software, support files, and design software such as Cadence or OrCAD. The design workstation 800 also includes a display 802 to facilitate a circuit design 810 or an RF filter-on-insulator wafer 812. A storage medium 804 is provided for tangibly storing the circuit design 810 or the RF filter-on-insulator wafer 812. The circuit design 810 or the RF filter-on-insulator wafer 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit design 810 or the RF filter-on-insulator wafer 812 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the present disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. A method of constructing a layer transferred radio frequency (RF) filter-on-insulator wafer, comprising:
exposing a front-side of a bulk RF wafer to a laser light source to form a modified layer at a predetermined depth along a horizontal length of the bulk RF wafer;
bonding the front-side of the bulk RF wafer to a front-side of a semiconductor handle wafer through an insulator layer;
forming an RF filter layer from the bulk RF wafer; and
selectively etching away the modified layer from the RF filter layer to the predetermined depth to complete the layer transferred RF filter-on-insulator wafer.

2. The method of claim 1, in which forming the RF filter layer comprises:
subjecting the bulk RF wafer bonded on the semiconductor handle wafer to an anneal process; and
fracturing the bulk RF wafer along the modified layer to expose portions of the modified layer.

3. The method of claim 2, further comprising removing the modified layer using a chemical mechanical planarization (CMP) to form the RF filter layer of the RF filter-on-insulator wafer.

4. The method of claim 1, in which forming the RF filter layer comprises:
surface grinding a backside of the bulk RF wafer to a predetermined thickness greater than the predetermined depth; and
removing the backside of the bulk RF wafer to expose the modified layer.

5. The method of claim 4, further comprising removing the modified layer using a wet/plasma etch to form the RF filter layer of the RF filter-on-insulator wafer.

6. The method of claim 1, in which the laser light source is provided by a femtosecond pulsed laser.

7. The method of claim 1, further comprising:
fabricating a first set of fingers in the RF filter layer;
fabricating a second set of fingers in the RF filter layer interdigitated with the first set of fingers to form a surface acoustic wave (SAW) filter; and
adjusting a pitch between the first set of fingers interdigitated with the second set of fingers in the RF filter layer to adjust a frequency of the SAW filter.

8. The method of claim 1, further comprising integrating a plurality of surface acoustic wave filters in the RF filter layer.

9. The method of claim 1, further comprising integrating a portion of the layer transferred RF filter-on-insulator wafer into an RF front end module, the RF front end module incorporated into at least one of a music player, a video player, an entertainment unit, a navigation device, a communications device, a personal digital assistant (PDA), a fixed location data unit, a mobile phone, and a portable computer.

10. A radio frequency (RF) filter-on-insulator wafer, comprising:
a semiconductor handle wafer;
an insulator layer directly on a front-side surface of the semiconductor handle wafer; and
an RF filter layer bonded to the front-side surface of the semiconductor handle wafer through the insulator layer, in which a thickness of the RF filter layer is in a range of 1.0 micron to 1.6 microns.

11. The RF filter-on-insulator wafer of claim 10, further comprising a plurality of integrated surface acoustic wave (SAW) filters in the RF filter layer.

12. The RF filter-on-insulator wafer of claim 10, in which the RF filter layer is comprised of lithium tantalate (LT) and/or lithium niobate (LN).

13. The RF filter-on-insulator wafer of claim 10, in which the semiconductor handle wafer is comprised of high resistivity silicon.

14. The RF filter-on-insulator wafer of claim 10, diced and integrated into an RF front end module, the RF front end module incorporated into at least one of a music player, a video player, an entertainment unit, a navigation device, a communications device, a personal digital assistant (PDA), a fixed location data unit, a mobile phone, and a portable computer.

15. A radio frequency (RF) front end module, comprising:
an acoustic filter, comprising a semiconductor handle wafer, an insulator layer directly on a front-side surface of the semiconductor handle wafer, and an RF filter layer bonded to the front-side surface of the semiconductor handle wafer through the insulator layer, in which a thickness of the RF filter layer is in a range of 1.0 micron to 1.6 microns; and
an antenna coupled to an output of the acoustic filter.

16. The RF front end module of claim 15, further comprising a plurality of surface acoustic wave (SAW) filters integrated in the RF filter layer.

17. The RF front end module of claim 15, in which the RF filter layer is comprised of lithium tantalate (LT) and/or lithium niobate (LN).

18. The RF front end module of claim 15, in which the semiconductor handle wafer is comprised of high resistivity silicon.

19. The RF front end module of claim 15, diced and incorporated into at least one of a music player, a video player, an entertainment unit, a navigation device, a communications device, a personal digital assistant (PDA), a fixed location data unit, a mobile phone, and a portable computer.
